(19) United States
(12) Patent Application Publication
(10) Pub. No.: US 2016/0197203 A1
(43) Pub. Date: Jul. 7, 2016

(54) Group III-N lateral schottky barrier diode and method for manufacturing thereof

(71) Applicants: IMEC VZW, Leuven (BE); Katholieke Universiteit Leuven, KU LEUVEN R&D, Leuven (BE)

(72) Inventor: Jie Hu, Leuven (BE)

(73) Assignees: IMEC VZW, Leuven (BE); Katholieke Universiteit Leuven, KU LEUVEN R&D, Leuven (BE)

(21) Appl. No.: 14/757,679

(22) Filed: Dec. 23, 2015

(30) Foreign Application Priority Data
Dec. 23, 2014 (EP) 14200017.3

(51) Int. Cl. H01L 29/872; H01L 29/205; H01L 29/66; H01L 29/20

(52) U.S. Cl. CPC H01L 29/8725; H01L 29/2003; H01L 29/205; H01L 29/66143

(57) ABSTRACT

A group III-N lateral Schottky diode is disclosed. The diode may include a substrate, a nucleation layer formed on the substrate, a buffer layer formed on the nucleation layer, and a group III-N channel stack formed on the buffer layer. The diode may further include, on the channel stack, a group III-N barrier containing aluminum, where the aluminum content of the barrier decreases towards the channel stack. The diode may further include a passivation layer formed on the group III-N barrier, a cathode formed in an opening through the passivation layer where the opening at least extends to the barrier, and an anode formed in another opening through the passivation layer partially extending into the barrier, the anode forming a Schottky contact with the barrier.

### CROSS-REFERENCE TO RELATED APPLICATION

The present application is a non-provisional patent application claiming priority to European Patent Application No. 14200017.3 filed Dec. 23, 2014, the contents of which are hereby incorporated by reference.

### TECHNICAL FIELD

The present disclosure relates to group III-N lateral Schottky barrier diodes. In particular, the disclosure relates to AlGaN/GaN lateral Schottky diodes.

### BACKGROUND

Group III-N lateral Schottky barrier diodes, such as AlGaN/GaN Schottky Barrier Diodes (SBDs), are attractive for high-power switching applications. They offer appealing properties such as fast switching speed, low on-state resistance, as well as a large breakdown voltage.

In order to obtain a low static power loss of such a Schottky diode in a switching circuit, the reverse diode leakage current and the forward diode voltage drop should be minimal.

N. Ikeda et al. disclose in “A Novel GaN Device with Thin AlGaN/GaN Heterostructure for High-power Applications,” Furukawa Review, No. 29 (2006), a dual Schottky metal barrier approach to reduce the static power loss. The anode contains two Schottky barrier metals. A low Schottky barrier metal is used to provide Ohmic-like behavior in the on-state, while a high Schottky barrier metal is used to pinch-off the channel in the off-state. This approach requires two Schottky metals having different work functions, which is typically not compatible with state-of-the-art CMOS processing.

Another approach is disclosed by W. Chen et al. in “High-performance AlGaN/GaN Lateral Feld-Effect Rectifiers Compatible with High Electron Mobility Transistors,” Applied Physics Letters, 92, 253501 (2008). Here, an enhancement-mode AlGaN/GaN High Electron Mobility Transistor (HEMT) is given a diode-like voltage-current behavior by electrically shortening the gate electrode and the source, thereby reducing the turn-on voltage of the transistor.

Hence, there is a need for a group III-N lateral Schottky diode offering a reduced static power loss, while maintaining a high switching speed and a low reverse leakage current.

Such a lateral Schottky diode should be manufacturable using state-of-the-art CMOS manufacturing processes, whereby preferably Au is not needed as contact metal for the anode and/or cathode contact.

Such a Schottky diode could have a conventional diode architecture. In particular, such a Schottky diode could allow for the monolithic integration of a group III-N lateral Schottky diode with a group III-N High Electron Mobility Transistor (HEMT).

### SUMMARY OF THE DISCLOSURE

A group III-N lateral Schottky diode is disclosed. The diode may include a substrate, a nucleation layer formed on the substrate, a buffer stack formed on the nucleation layer, and a group III-N channel layer formed on the buffer stack. On the channel layer, the diode may further include a group III-N barrier containing aluminum, where the aluminum content of the barrier decreases towards the channel layer. The diode may further include a passivation layer formed on the group III-N barrier, a cathode formed in an opening through the passivation layer, where the opening extends at least to the barrier, and an anode formed in another opening through the passivation layer, partially extending into the barrier, the anode forming a Schottky contact with the barrier.

In an example embodiment, the group III-N barrier may include a first barrier layer formed on the channel layer and a second barrier layer formed on the first barrier layer, where the aluminum content of the first barrier layer is less than the aluminum content of the second barrier layer. The first barrier layer may have an aluminum content in the range of 1 at. % to 50 at. %. The first barrier layer and the second barrier layer may have a layer thickness in the range of 1 nm to 50 nm.

The channel layer may be a gallium nitride channel layer in physical contact with an aluminum gallium nitride barrier.

The cathode opening may extend at least through the passivation layer, forming an Ohmic contact between the cathode and the two-dimensional electron gas present at the interface between the channel layer and the barrier. In an example embodiment, the anode opening may extend into the first barrier layer.

The diode may further include an edge termination dielectric layer isolating the anode from the passivation layer and from the upper surface of the second barrier layer exposed in the anode opening. Optionally, this edge termination dielectric layer may further isolate the anode from any surface of the second barrier layer exposed in the anode opening and from part of the surface of the first barrier layer exposed in the extended anode opening.

A method for manufacturing a group III-N lateral Schottky diode according to any of the foregoing paragraphs is disclosed. The method may include providing a substrate, forming a nucleation layer on the substrate, forming a buffer stack on the nucleation layer, and forming a group III-N channel layer on the buffer stack. The method may further include forming on the channel layer a group III-N barrier containing aluminum, where the aluminum content of the barrier decreases towards the channel stack. The method may further include forming a passivation layer on the group III-N barrier, forming an anode in an opening in the passivation layer, where the opening extends into the barrier. The anode may be isolated at least from the passivation layer by an edge termination dielectric layer, and the anode may form a Schottky contact with the barrier. The method may further include forming a cathode in an opening through the passivation layer, where the opening at least extends to the barrier, and where the cathode forms an Ohmic contact with a two-dimensional electron gas present at the interface between the channel layer and the barrier.

The group III-N barrier may be formed by forming a first barrier layer on the channel stack and forming a second barrier layer on the first barrier layer, where the aluminum content of the first barrier layer is less than the aluminum content of the second barrier layer.

The anode may be formed by forming the opening through the passivation layer, forming the dielectric layer on the sidewalls and on the bottom of the opening, extending part of the opening through the dielectric layer into the barrier, and forming an anode in the opening to create a Schottky contact with the barrier.

Alternatively, the anode may be formed by forming the opening through the passivation layer, extending the opening into the barrier, forming the dielectric layer on the sidewalls and on the outer part of the bottom of the opening, and forming an anode in the opening to create a Schottky contact with the barrier.

### BRIEF DESCRIPTION OF THE DRAWINGS

For the purpose of teaching, drawings are added. These drawings illustrate some aspects and embodiments of the disclosure. They are only schematic and non-limiting. The size of some of the elements may be exaggerated and not drawn on scale for illustrative purposes. The dimensions and the relative dimensions do not correspond to actual reductions to practice of the disclosure. Like features are given the same reference number.

FIG. 1 is a graph showing a typical diode characteristic of a group III-N Schottky barrier diode.

FIG. 2 illustrates a cross-section of a Schottky barrier diode according to an example embodiment.

FIG. 3 is a graph showing a TCAD simulation of the potential energy band diagram of a Schottky barrier diode with double AlGaN barriers in the region between the anode and the cathode according to an example embodiment.

FIG. 4 is a graph showing a TCAD simulation illustrating the shift in Schottky barrier height of a Schottky barrier diode according to an example embodiment.

FIG. 5 illustrates another cross-section of a Schottky barrier diode according to an example embodiment.

FIG. 6 illustrates another cross-section of a Schottky barrier diode according to an example embodiment.

### DETAILED DESCRIPTION

The present disclosure is described with respect to particular embodiments and with reference to certain drawings, but the disclosure is not limited thereto. Furthermore, the terms first, second, and the like in the description are used for distinguishing between similar elements and not necessarily for describing a sequence, either temporally, spatially, in ranking, or in any other manner. It is to be understood that the terms so used are interchangeable under appropriate circumstances and that the embodiments of the disclosure described herein are capable of operation in other sequences than described or illustrated herein. Moreover, the terms top, under, and the like in the description are used for descriptive purposes and not necessarily for describing relative positions. It is to be understood that the terms so used are interchangeable under appropriate circumstances and that the embodiments of the disclosure described herein are capable of operation in other orientations than described or illustrated herein.

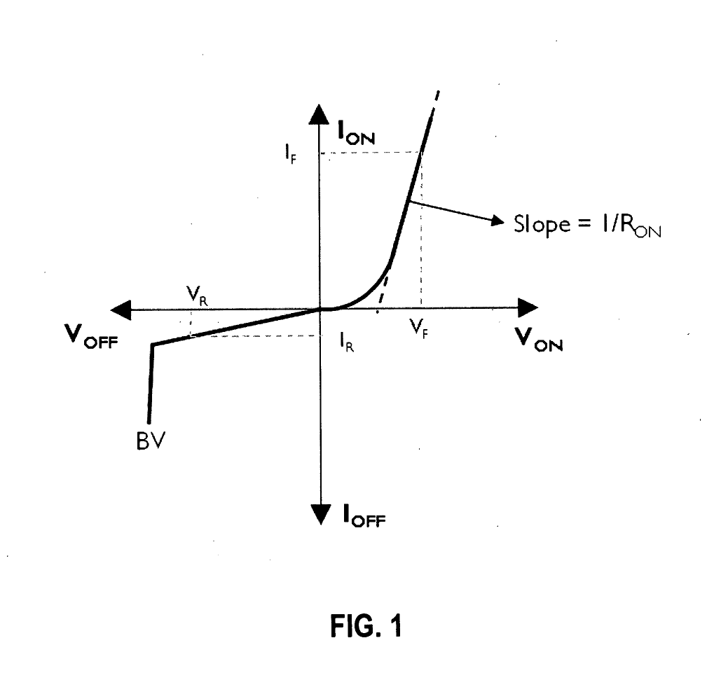

FIG. 1 shows a typical diode characteristic of a group III-N Schottky diode, such as an AlGaN/GaN Schottky diode. The forward voltage (V_{F}) of such a Schottky diode depends on the turn-on voltage (V_{T}), the on-state resistance (R_{ON}), and the forward current (I_{F}) of the diode. According to example embodiments of this disclosure, both the turn-on voltage and the on-state resistance may be reduced, thereby lowering the forward voltage and the static power loss, while maintaining other properties of the diode, such as its fast switching speed and its large breakdown voltage (BV).

The turn-on voltage mainly depends on the barrier height of the Schottky barrier. The on-state resistance of the Schottky diode depends on the density and mobility of a two-dimensional electron gas (2DEG) 7 formed at the interface between the group III-N channel stack 5 and group III-N barrier 6. According to example embodiments of this disclosure, a reduction in turn-on voltage and the on-state resistance is achieved by engineering the group III-N barrier 6.

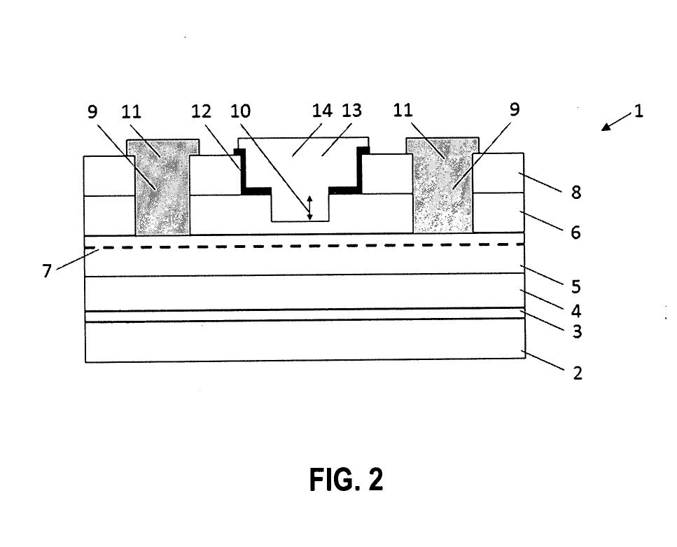

FIG. 2 shows a cross-section of a Schottky barrier diode according to an example embodiment. The group III-N lateral Schottky diode 1 comprises a substrate 2, a nucleation layer 3 formed on the substrate 2, a buffer stack 4 formed on the nucleation layer 3, and a group III-N channel 5 formed on the buffer stack 4. The Schottky diode 1 also includes, on the channel layer 5, a group III-N barrier 6 containing aluminum, where the aluminum content of the barrier 6 decreases towards the channel layer 5, a passivation layer 8 formed on the group III-N barrier 6, and a cathode 11 formed in a cathode opening 9 through the passivation layer 8. In the present example, the cathode opening 9 at least extends through the barrier 6. Further, an anode 13 is formed in an anode opening 14 through the passivation layer 8 thereby partially extending a distance 10 into the barrier 6, the anode forming a Schottky contact with the barrier 6. The cathode opening 9 may extend to the barrier 6. Optionally, the cathode opening 9 may further extend into the barrier 6.

The substrate 2 can be any substrate used in the manufacturing of group III-N devices, such as silicon, silicon-carbide or sapphire. On top of the substrate 2, the semiconducting layers of the Schottky barrier diode 1 are epitaxially grown, and the nucleation layer 3 is configured to reduce the mismatch between the substrate 2 and the buffer stack 4. An advantage of the disclosed diode is that the epitaxially grown stack is compatible with the manufacturing of the group III-N High Electron Mobility Transistors (HEMT), thereby allowing monolithical integration of the disclosed diode with HEMTs on a single substrate.

On the nucleation layer 3, a buffer stack 4 is present. In the case of a gallium nitride Schottky diode 1, the buffer stack 4 typically contains several aluminum gallium nitride layers having varying aluminum content and layer thicknesses. The aluminum content and the layer thickness are selected to improve the buffer breakdown voltage and/or wafer bow, thereby allowing a high quality gallium nitride channel stack 5 to be grown on top.

On the buffer stack 4, a group III-N channel layer 5 is present.

A group III-N barrier 6 containing aluminum is located on the channel layer 5. The aluminum content of the barrier 6 decreases towards the channel layer 5.

Due to the polarization effect and the potential energy band offset between the channel layer 5 and the barrier 6, a two-dimensional electron gas (2DEG) 7 is formed in the channel layer 5 near the interface with the barrier 6. In the on-state, an electrical current flows from the anode 13 to the cathode 11 through the 2DEG layer 7, which has a high electron density and high electron mobility.

On top of the barrier 6, a passivation layer 8 is present. The passivation layer 8 passivates dangling bonds at the surface of the barrier 6 and shields the epitaxial stack from external contamination.

In the passivation layer 8, a cathode opening 9 and an anode opening 14 are created to respectively form the Ohmic cathode 11 and the Schottky barrier anode 13. The cathode opening 9 extends at least to the barrier 6, and may extend into or through the barrier 6. The metal or metals of the cathode then forms a low Ohmic contact with the 2DEG 7. A dielectric layer 12 is deposited in the anode opening 14, covering the exposed surface of the barrier 6 and the sidewalls of the passivation layer 8. The anode opening 14 extends through the passivation layer 8 and through the dielectric layer 12 a distance 10 partially into the barrier 6. The metal or metals of the anode then forms a Schottky contact with the lower part of the barrier 6 having a lower aluminum content. By varying the depth of the cathode opening 9 and anode opening 14, the cathode 11 and the anode 13 can contact parts of the barrier layer 8 having a different aluminum content.

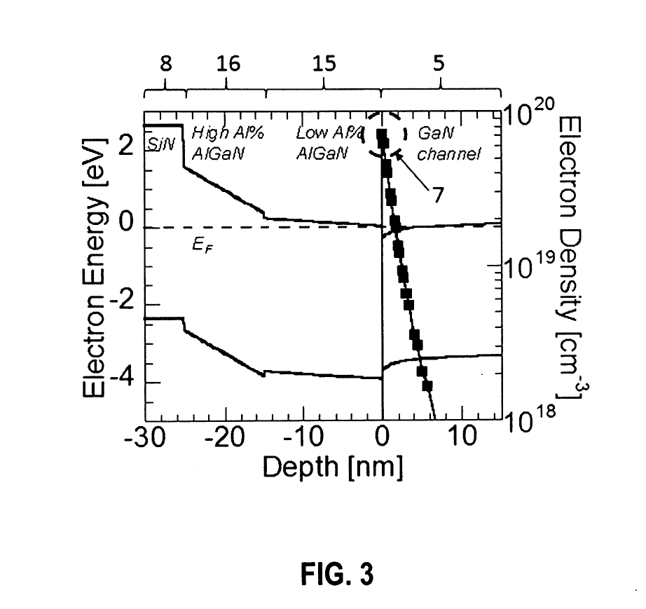

FIG. 3 shows a simulated potential energy band diagram (solid lines) and the 2DEG density (filled squares) illustrating the effect of having a group III-N barrier 6 with decreasing aluminum content towards the channel layer 5 for a gallium nitride Schottky diode. Here, the barrier 6 contains two or more AlGaN layers. This stack of AlGaN layers allows a high electron density of the 2DEG 7 to form in the AlGaN 6/GaN 5 quantum well resulting in the desired low on-state resistance during on-state operation. Here, a SiN layer is used as passivation layer 8, but other dielectric layers can be used as well.

The Schottky metal of the anode 13 is in contact with the AlGaN barrier 6 having a lower aluminum content, e.g., nearer to the channel layer 6. Hence, the Schottky barrier height ΦB will be low. In the access region between the anode and cathode, the barrier layer is not recessed, resulting in a low R_{ON}.

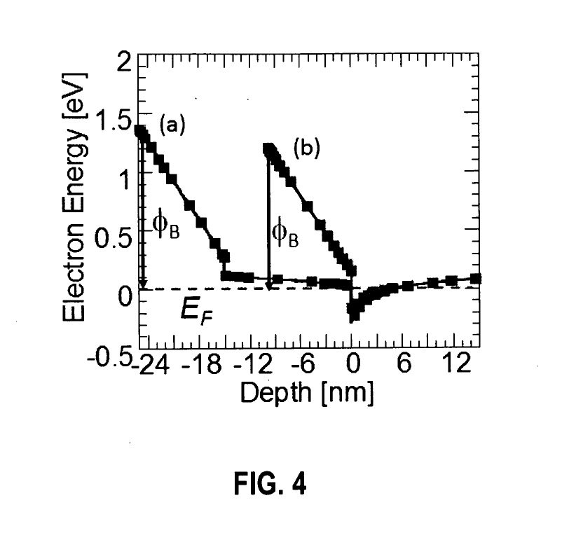

FIG. 4 illustrates the reduction of the Schottky barrier height ΦB by recessing the anode 13 a distance 10 into a portion 16 of AlGaN barrier 6 having a higher aluminum content. This reduced Schottky barrier height ΦB allows the diode 1 to turn on earlier as it has a lower turn-on voltage. In the region between the anode 13 and the cathode 11, the full AlGaN barrier 6 remains, resulting in a low R_{ON}. Hence, a low forward voltage of the diode 1 during on-state operation is obtained.

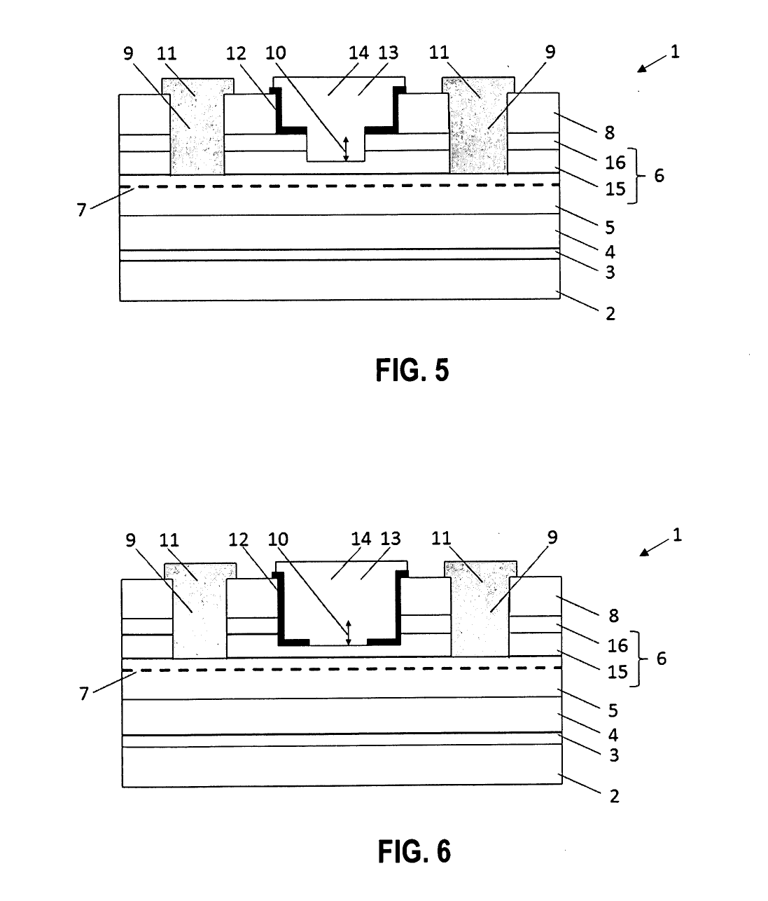

FIG. 5 shows a cross-section of Schottky barrier diode 1 having characteristics as illustrated by FIG. 3 and FIG. 4. This embodiment differs from the embodiment illustrated by FIG. 2 in that the group III-N barrier 6 now comprises a first barrier layer 15 formed on the channel layer 5 and a second barrier layer 16 formed on the first barrier layer 15. The aluminum content of the first barrier layer 15 is less than the aluminum content of the second barrier layer 16. Here, the cathode opening 9 is etched through the passivation layer 8 to or into the barrier layer 6, or even into the channel layer 5 to electrically contact the 2DEG 7.

FIG. 6 shows another embodiment. This embodiment differs from the embodiment illustrated by FIG. 5 in the shape of the anode opening 14. In this embodiment, the portion of the anode opening 14 in the passivation layer 8 has the same width as the portion of the anode opening 14 in the barrier layer 6. The channel layer 5 may be a gallium nitride channel layer, while the group III-N barrier 6 may be an aluminum gallium nitride barrier. In this configuration, the first barrier layer 15 typically has an aluminum content in the range of 1 at. % to 50 at. % (atomic percentage). The aluminum content of the second barrier layer 16 may then vary between the effective aluminum content of the first barrier layer 15 and 100 at. %. The layer thickness of the first barrier layer 15 and of the second barrier layer 16 is preferably in the range of 1 nm to 50 nm (nanometer).

To further reduce the static power loss, the leakage current can be reduced using edge termination with a dielectric layer 12. The dielectric layer 12 suppresses the high electric field at the corners of the Schottky anode 13 in the off-state. This edge termination is typically formed by depositing a dielectric layer, such as silicon nitride, silicon oxide, or alumina oxide, at least in the corners of the Schottky barrier anode 13.

FIG. 5 illustrates a first implementation of the edge termination. The anode opening 14 is stepwise, having a larger dimension in the passivation layer 8 than in the barrier 6, such that, within the anode opening 14, part of the upper surface of the second barrier layer 16 is exposed. The dielectric layer 12 covers the passivation layer 8 isolating the anode 13 therefrom, and the dielectric layer 12 covers the exposed upper surface of the second barrier layer 16. In the smaller sized part of the anode opening 14, the anode 13 contacts the exposed sidewalls of the second 16 and first 15 barrier layers, as well as the first barrier layer 15 at the bottom of the anode opening 14.

FIG. 6 illustrates an alternative implementation of the edge termination. Here, the anode opening 14 has a constant width dimension when extending into the diode 1. The dielectric layer 12 covers the passivation layer 8 and the exposed sidewalls of the second 16 and first 15 barrier layers. This isolates the anode 13 from the passivation layer 8 and the second barrier layer 16. At the bottom of the anode opening 14, an opening in the edge termination dielectric layer 12 is present to allow direct contact between the anode 13 and the first barrier layer 15.

A method for manufacturing a group III-N lateral Schottky diode 1 according to any of the foregoing paragraphs is disclosed. The method may include providing a substrate 2, forming a nucleation layer 3 on the substrate 2, forming a buffer stack 4 on the nucleation layer 3, and forming a group III-N channel layer 5 on the buffer stack 4. The method may further include forming on the channel layer 5 a group III-N barrier 6 containing aluminum, where the aluminum content of the barrier 6 decreases towards the channel stack 5. The method may further include forming a passivation layer 8 on the group III-N barrier 6 and forming an anode 13 in an anode opening 14 in the passivation layer 8 extending into the barrier 6. The anode 13 may be isolated at least from the passivation layer 8 by an edge termination dielectric layer 12, and the anode may form a Schottky contact with the barrier 6. The method may further include forming a cathode 11 in a cathode opening 9 through the passivation layer 8, at least extending to the barrier 6. The cathode 11 may form an Ohmic contact with a two-dimensional electron gas 7 present at the interface between the channel layer 5 and the barrier 6.

The group III-N barrier 6 can be formed by forming a first barrier layer 15 on the channel stack 5 and forming a second barrier layer 16 on the first barrier layer 15, where the aluminum content of the first barrier layer 15 is less than the aluminum content of the second barrier layer 16. The channel layer 5 may be a gallium nitride channel layer, and the barrier 6 may be an aluminum gallium nitride barrier. The first barrier layer 15 may have an aluminum content in the range of 1 at. % to 50 at. %, and the second barrier layer 16 may have an aluminum content between the aluminum content of the first barrier layer 15 and 100 at. %. The first barrier layer 15 and the second barrier layer 16 may have a layer thickness in the range of 1 nm to 50 nm.

The anode 13 can be formed by forming the anode opening 14 through the passivation layer 8, forming the dielectric layer 12 on the sidewalls and on the bottom of the anode opening 14, extending part of the anode opening 14 a distance 10 through the dielectric layer 12 into the barrier 6, and then forming the anode 13 in the anode opening 14 to create a Schottky contact with the barrier 6. The resulting device is illustrated by FIG. 5.

Alternatively, the anode 13 can be formed by forming the anode opening 14 through the passivation layer 8, extending the anode opening 14 a distance 10 into the barrier 6, forming the dielectric layer 12 on the sidewalls and on the outer part of the bottom of the anode opening 14, and then forming the anode 13 in the anode opening 14 to create a Schottky contact with the barrier 6. This resulting device is illustrated by FIG. 6.

In the foregoing methods for manufacturing a group III-N Schottky diode 1, the anode 13 is formed prior to the cathode 11. In alternative methods, the cathode 11 is formed prior to the anode 13. These alternative methods differ from the foregoing methods in that, after forming the passivation layer 8 on the group III-N barrier 6, a cathode opening 9 is formed through the passivation layer 8, where the cathode opening 9 at least extends to the barrier 6. In the cathode opening 9, the cathode 11 is formed. Thereafter, the anode opening 14 is formed through the passivation layer 8, where the anode opening 14 partially extends a distance 10 into the barrier 6. In the anode opening 14, the anode 13 is formed, creating a Schottky contact with the barrier 6.

The disclosed architecture of a group III-N Schottky barrier diode, in particular of a lateral AlGaN/GaN Schottky diode, allows the reduction of static power loss during both the on-state and the off-state.

What is claimed is:

1. A group III-N lateral Schottky diode comprising:
a substrate;
a nucleation layer formed on the substrate;
a buffer stack formed on the nucleation layer;
a group III-N channel layer formed on the buffer stack;
a group III-N barrier formed on the group III-N channel layer, wherein the group III-N barrier has an aluminum content that decreases towards the group III-N channel layer;
a passivation layer formed on the group III-N barrier;
a cathode formed in a first opening through the passivation layer, wherein the first opening at least extends to the group III-N barrier; and
an anode formed in a second opening through the passivation layer, wherein the second opening partially extends into the group III-N barrier, and wherein the anode forms a Schottky contact with the barrier.

2. The diode of claim 1, wherein:
the group III-N barrier comprises a first barrier layer formed on the group III-N channel layer and a second barrier layer formed on the first barrier layer; and
an aluminum content of the first barrier layer is less than an aluminum content of the second barrier layer.

3. The diode of claim 2, wherein:
the group III-N channel layer is a gallium nitride channel layer; and
the group III-N barrier is an aluminum gallium nitride barrier.

4. The diode of claim 3, wherein:
the first barrier layer has an aluminum content in the range of 1 at. % to 50 at. %.

5. The diode of claim 4, wherein:
the first barrier layer and the second barrier layer have a layer thickness in the range of 1 nm to 50 nm.

6. The diode of claim 2, wherein:
a two-dimensional electron gas is located at an interface between the group III-N channel layer and the group III-N barrier; and
the cathode forms an Ohmic contact with the two-dimensional electron gas.

7. The diode of claim 2, wherein the second opening extends into the first barrier layer.

8. The diode of claim 7, further comprising:
an edge termination dielectric layer isolating the anode from the passivation layer and from an upper surface of the second barrier layer.

9. The diode of claim 8, wherein:
the edge termination dielectric layer isolates the anode from all surfaces of the second barrier layer; and
the edge termination dielectric layer isolates the anode from part of a surface of the first barrier layer exposed in the second opening.

10. A method for manufacturing a group HI-N lateral Schottky, the method comprising:
providing a substrate;
forming a nucleation layer on the substrate;
forming a buffer stack on the nucleation layer;
forming a group III-N channel layer on the buffer stack;
forming a group III-N barrier on the group III-N channel layer, wherein the group III-N barrier has an aluminum content that decreases towards the group III-N channel layer;
forming a passivation layer on the group III-N barrier;
forming a cathode in a first opening through the passivation layer, wherein the first opening at least extends to the group III-N barrier, and wherein the cathode forms an Ohmic contact with a two-dimensional electron gas located at an interface between the group III-N channel layer and the group III-N barrier; and
forming an anode in a second opening in the passivation layer, wherein the second opening extends into the group III-N barrier, wherein the anode is isolated at least from the passivation layer by an edge termination dielectric layer, and wherein the anode forms a Schottky contact with the group III-N barrier.

11. The method of claim 10, wherein forming a group III-N barrier comprises:
forming a first barrier layer on the group III-N channel layer; and
forming a second barrier layer on the first barrier layer, wherein the aluminum content of the first barrier layer is less than the aluminum content of the second barrier layer.

12. The method of claim 10, wherein forming an anode comprises:
forming the second opening through the passivation layer;
forming the edge termination dielectric layer on the sidewalls and on the bottom of the second opening;
extending part of the second opening through the edge termination dielectric layer into the group III-N barrier; and
forming an anode in the second opening, the anode forming a Schottky contact with the group III-N barrier.

13. The method of claim 10, wherein forming an anode comprises:
forming the second opening through the passivation layer;
extending the second opening into the barrier;
forming the edge termination dielectric layer on the sidewalls and on an outer part of the bottom of the second opening; and
forming an anode in the second opening, the anode forming a Schottky contact with the group III-N barrier.
